(19) United States
(12) Patent Application Publication
(10) Pub. No.: US 2004/0037059 A1
(43) Pub. Date: Feb. 26, 2004

(54) Integrated circuit package with spacer

(76) Inventors: Leon Stiborek, Dallas, TX (US); Jeremias P. Libres, Garland, TX (US)

Correspondence Address: TEXAS INSTRUMENTS INCORPORATED, P O BOX 655474, M/S 3999, DALLAS, TX, 75265

(21) Appl. No.: 10/224,904

(22) Filed: Aug. 21, 2002

(51) Int. Cl. H05K 1/18

(52) U.S. Cl. 361/764

(57) ABSTRACT

A packaged integrated circuit including a substrate 310 having first and second opposing surfaces, wherein the first surface has a central chip pad location and a peripheral area surrounding the chip pad location. At least a portion of the peripheral area is covered by a spacer 330. An integrated circuit chip 300 is mounted on the chip pad location, and a heatsink 350 is mounted over the first surface of the substrate and attached to the chip and to the spacer. The spacer can be continuous and made to surround the chip pad location, or it can be discontinuous and placed at discrete locations in the peripheral area.

### CROSS-REFERENCE TO RELATED APPLICATIONS

This application is related to application Ser. No. ______ (attorney docket number TI-34870).

### BACKGROUND OF THE INVENTION

This invention is in the field of integrated circuit packages and packaging methods.

The demand for a reduction in size and an increase in complexity and performance of electronic components has driven the industry to produce smaller and more complex integrated circuits (ICs). These same trends have forced the development of IC packages having small footprints, high lead counts, and better electrical and thermal performance. At the same time, these IC packages are required to meet accepted industry standards. Power dissipation is a particular challenge since higher performance ICs produce more thermal energy, and the smaller packages of today allow the designer few options through which to dissipate this energy.

In one prior art approach, shown in FIG. 1, a ceramic ball grid array package is fitted with a copper-tungsten 1id that serves both as a thermal sink as well as to protect the integrated circuit. The chip 100 is mounted face-down on a ceramic substrate 110 with solder bumps 120. Underfill 130 protects the active surface of the chip and strengthens the chip-to-substrate attachment. Thermally conductive compound 140 is compressed between the chip backside and the inner surface of lid 150. Lid 150 is attached to substrate 110 with adhesive 160. Solder balls 170 connect the assembly to the next level of interconnection, such as a printed circuit board. While this packaging technology has been used for some time in industry, it suffers from various disadvantages, including poor thermal performance as a result of the long thermal path from the chip through the lid. This is true even when a large heatsink is attached to lid 150. As is also clear from FIG. 1, the attachment of lid 150 to substrate 110 consumes substantial substrate area (in some cases, up to 50% of the substrate area), which otherwise could be used as mounting locations for passive devices, for example.

A second prior art approach, shown in FIG. 2, overcomes some of the disadvantages of the FIG. 1 package. This direct lid attach package again includes a chip 200 mounted face-down on a substrate 210 with solder bumps 220. Underfill 230 is inserted between chip and substrate as above. However, instead of a lid sealed to the substrate, lid 250 is only attached to the backside of chip 200. The sole mechanical support for the lid is a thermally-conductive adhesive 240. The package is completed by solder balls 270 on the bottom of the substrate. An advantage of this approach is that the relatively simple lid can be attached more efficiently and at lower cost than in the traditional approach shown in FIG. 1. The most obvious advantage, however, is that the lid consumes no substrate surface area.

While the technology shown in FIG. 2 solves some of the problems inherent in the traditional approach, it still suffers from disadvantages. In particular, the mechanical integrity of the lid to chip interface is questionable in view of the limited area over which the bond occurs relative to the lid and chip size. The thermally-conductive adhesive necessary to support the lid—a primerless, two-part polysiloxane-based adhesive made by reacting polydimethyl siloxane, an organosilicon compound, a polysiloxane, and a silane, in the presence of a catalyst—is also expensive and is considered exotic by many in the industry. Some prior art approaches avoid the exotic thermally-conductive adhesive by using solder as the means for attaching the lid to the chip backside. This, of course, requires that the chip backside be covered with metal, which is itself an expensive process step. Solder as a method of attaching the lid also does not lend itself to rework and replacement of the IC, a disadvantage for microprocessors which are often upgradable. Additionally, precise mounting of the lid to the chip is difficult. In particular, it is difficult to achieve a uniform “bond line”, or interface between the chip backside and the lid because of the tendency of the lid to tilt and rotate. Uniformity at this interface is important for both thermal performance and mechanical integrity. It is therefore apparent that a need exists in the industry for an improved package and packaging method for products that benefit from efficient thermal dissipation.

### BRIEF SUMMARY OF THE INVENTION

In one embodiment of the invention, a packaged integrated circuit is disclosed. It includes a substrate having first and second opposing surfaces, wherein the first surface has a central chip pad location and a peripheral area surrounding the chip pad location. At least a portion of the peripheral area is covered by a spacer. An integrated circuit chip is mounted on the chip pad location, and a heatsink is mounted over the first surface of the substrate and attached to the chip and to the spacer. The spacer can be continuous and made to surround the chip pad location, or it can be discontinuous and placed at discrete locations in the peripheral area.

In another embodiment of the invention, another packaged integrated circuit is disclosed. This packaged IC includes a substrate having first and second opposing surfaces, wherein the first surface has a central chip pad location and a peripheral area surrounding the chip pad location. The peripheral area is covered with mold compound of a certain thickness. An integrated circuit chip is mounted on the chip pad location, the chip having a top surface away from the first surface of the substrate. The top surface of the chip being a distance from the first surface of the substrate that is less than the certain thickness of the mold compound. A heatsink is mounted over the first surface of the substrate and is attached to the chip and to the mold compound. The mold compound can be continuous and made to surround the chip pad location. Or it can be discontinuous and placed at discrete locations in the peripheral area. The packaged IC can further include a passive component mounted on the first surface of the substrate, wherein the mold compound covers the passive component.

In still another embodiment of the invention, a method of packaging an integrated circuit is disclosed. The method includes the steps of providing a substrate having first and second opposing surfaces, wherein the first surface has a central chip pad location and a peripheral area surrounding the chip pad location; covering at least a portion of the peripheral area with a spacer; mounting an integrated circuit chip on the chip pad location; and attaching a heatsink to the chip and to the spacer.

An advantage of the invention is that it provides an economical and reliable way of mounting a heatsink on an integrated circuit. The spacer both supports the weight of the heatsink and helps to protect the chip from the forces involved in assembling the package. It is also compatible with peripheral surface-mounted passive components such as capacitors.

### BRIEF DESCRIPTION OF THE SEVERAL VIEWS OF THE DRAWINGS

The drawings are intended to aid in understanding embodiments of the invention. One skilled in the art will appreciate that the drawings are not to scale; in particular, the vertical dimension is typically exaggerated to better show the details of the embodiments.

FIG. 1 is a cross-sectional diagram of a prior art lidded IC package in which the lid is supported by the package substrate.

FIG. 2 is a cross-sectional diagram of a prior art lidded IC package in which the lid is attached directly to the chip backside, with the interface between the lid and the chip being the sole support for the lid.

FIG. 3 is a cross-sectional diagram of an embodiment packaged IC in which a spacer ring is used to support and stabilize the heatsink.

FIGS. 4a to 4c show various means of attaching the packaged IC to a printed circuit board, including solder balls, solder columns with an interposer, and direct-attach columns.

FIG. 5 is a cross-sectional diagram of an embodiment packaged IC in which the chip backside extends above the surrounding spacer ring.

FIG. 6 is a cross-sectional diagram of an embodiment packaged IC including a passive component mounted on the substrate.

FIG. 7a is a cross-sectional diagram of an embodiment packaged IC in which the spacer ring has a textured top surface.

FIG. 7b is a plan view of the IC of FIG. 7a, except that the heatsink, adhesive, and thermal compound are not shown for the sake of clarity.

FIG. 8a is a cross-sectional diagram of an embodiment packaged IC in which the spacer ring has a top surface textured with channels having sloping sides.

FIG. 8b is a plan view of the IC of FIG. 8a, except that the heatsink, adhesive, and thermal compound are not shown for the sake of clarity.

FIGS. 9a to 9c are cross-sectional diagrams of an embodiment packaged IC in which the spacer ring and heatsink are designed with key-like locking features.

FIG. 10 is a plan view of an embodiment substrate showing a spacer consisting of discontinuous patches arranged in the peripheral region of the substrate.

FIG. 11a is a cross-sectional diagram of a mold die over a chip and substrate.

FIG. 11b is a plan view of FIG. 11a showing the relation of the mold die features to the chip.

FIG. 11c is a cross-sectional diagram of a substrate with molded spacer produced using the process shown in FIG. 11a.

FIG. 12a is a cross-sectional diagram of a mold die/plunger combination over a chip and substrate.

FIG. 12b is a plan view of FIG. 12a showing the relation of the mold die features to the chip.

FIG. 12c is a cross-sectional diagram of a substrate with molded spacer produced using the process shown in FIG. 12a.

FIG. 13 is a cross-sectional diagram of a substrate in a block molding cavity.

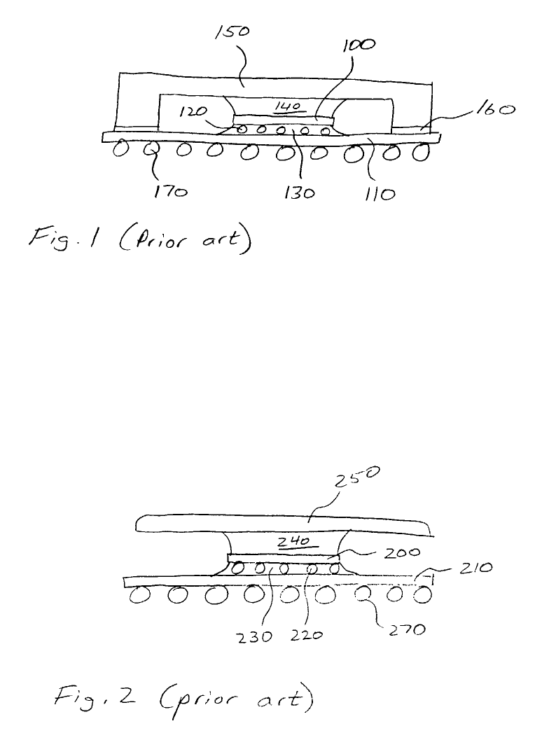

### DETAILED DESCRIPTION OF THE INVENTION

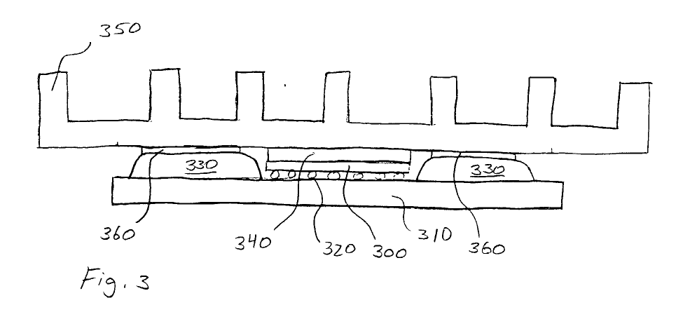

In various embodiments of the invention described herein, a spacer is affixed to the substrate. The spacer has a top surface that is in approximately the same plane as the chip backside, and hence provides mechanical support for, and a means for precisely mounting, a heatsink attached directly to the chip backside. The spacer thickness can be selected to produce a negative offset with the chip backside (i.e. the spacer thickness is greater than the stack height of the chip backside, as in FIG. 3), or it can be selected to produce a positive offset with the chip backside (i.e. the spacer thickness is less than the height of the chip backside, as in FIG. 5), depending upon the particular requirements of the chip being packaged. For example, in packages in which thermal performance is of utmost concern, the interface between the chip backside and the heatsink is preferably as thermally conductive and uniform as possible. The material selected for the spacer, therefore, is preferably one that can be applied in a precise thickness and that can maintain the desired thickness when subjected to force (e.g. when the package is inserted in a socket) or thermal stress (e.g. during the heat cycling that occurs when the circuitry on the chip is turned on and off). Such a situation would likely benefit from the negative offset arrangement, and from a spacer material with a high modulus of elasticity, such as silica-filled epoxy mold compound. In other situations requiring more flexibility (e.g. with a laminate or flex tape substrate) or compressibility, a more compliant spacer material such as silicone rubber or a polyester film can be used. The spacer in some embodiments includes surface features designed to enhance the adhesion of the heatsink to the spacer. In some embodiments, the spacer is molded over the substrate surface and can be molded over passive components mounted on that surface. The inventive technology disclosed herein therefore solves the problems of the prior art and does so in an economical way.

FIG. 3 shows an embodiment of the invention in which integrated circuit chip 300 is mounted face-down on substrate 310 using solder bumps 320, for example. In the alternative, solder columns, or metal (e.g. copper or gold) balls, columns, or similar means could be used to mount chip 300 to substrate 310. Substrate 310 is a multi-metal-layer ceramic in this embodiment, but could alternatively be a single- or multi-metal layer laminate (of bismaleimide triazine or epoxy, for example) or a flex tape (of polyimide, for example). Substrate 310 is approximately 1.9 mm thickness. Chip 300 is silicon and is approximately 610 μm in thickness in this embodiment. Solder bumps 320 are tin/lead, tin/silver or similar material and are approximately 75 to 90 μm in height. Spacer ring 330 can be molded, laminated, or attached with adhesive to substrate 310. It can be thermally-conductive or thermally-insulative, but is preferably thermally-conductive so as to add more heat-dissipating surface area to the assembly. If molded, the ring is preferably a silica-filled epoxy mold compound. If laminated, the film is preferably a polyimide or polyester film or similar material. In the alternative, the film can be an elastomeric material with a low modulus of elasticity, such as silicone rubber or a similar material. Such a material can be applied in liquid or gel form and is preferably self-curing. In the alternative, a preformed pad such as the Sil-Pad™ available from Bergquist Company or the In Sil-Pad-8™ pad from Aavid Thermalloy, L.L.C., can be used as the spacer. The Sil-Pad™, for example, is a silicone rubber binding agent on a fiberglass support. It is typically metal-filled for enhanced thermal conductivity. An elastomeric material such as silicone rubber is capable of controlled compressibility, which offers the advantage of allowing the package to be inserted in a socket, for example, without undue risk of damage since the force required to insert the package into the socket can be at least partially absorbed by the spacer ring. The movement allowed by such a spacer material can be a disadvantage in some applications, however, particularly those in which the quality of the interface between the backside of the chip and the heatsink is paramount.

The thickness of spacer ring 330 is selected in this embodiment to produce a negative offset with the chip backside. A preferred arrangement is to achieve an interface between the chip backside and the heatsink that includes no more than about 50 to 100 μm of thermal compound, thermal grease, or other similar thermal conductor. A typical thermal compound is metal-oxide (e.g. aluminum or copper)-filled silicone. Synthetic, so-called “dry”, alternatives are also applicable. The Sil-Pad™ and In-Sil-8™ pads mentioned above are also alternatives to conventional thermal compounds. Whatever thermal compound is selected, the preference is for as thin a layer of thermal conductor as is possible to apply uniformly. Proper thermal performance of the package relies heavily on achieving uniformity at the chip-heatsink interface. Note that the thickness of thermal compound 340 also comprehends the thickness of optional adhesive 360 used to attach heatsink 350 to spacer ring 330. If used, adhesive 360 can be selected to be a high-modulus material such as epoxy or acrylic, or a lower modulus material such as one of the silicone pads described above coated with an acrylic adhesive, for example. The selection between low- or high-modulus material in combination with the selection of the spacer material determines the movement allowed by the heatsink 350 relative to the substrate 310. In situations demanding the best possible heat dissipation from the IC, the interface between the chip backside and the heatsink must be uniform and precisely controllable, which suggests that higher modulus materials be selected for the spacer and adhesive. In situations where the substrate is subject to temperature-induced flexing, or the assembly is to be pressed into a socket, for example, lower-modulus materials are likely to be preferable. In addition to material selection, the form in which the adhesive is applied is also a factor. The adhesive can be screened on to the spacer, applied with a syringe or applied by pin transfer. The adhesive silicone pads offer another alternative and are the preferred option, not only because of the variety of thicknesses available, but also because of the precise control of thickness that is possible. One skilled in the art will appreciate that other similar adhesives could be used, keeping in mind, however, that an object of this approach is to achieve a uniform and well-controlled interface between the chip backside and the heatsink. The selected adhesive is preferably of a type that can be applied in a well-controlled thickness. In this embodiment, the chip and ball stack height is approximately 685 μm in total, and assuming 50 μm of thermal compound and 25 μm of adhesive 360, the ring 330 is approximately 710 μm thick. The heatsink is preferably finned, but can alternatively be of any appropriate shape and size. It is preferably made of a material such as aluminum, copper, aluminum nitride, beryllium oxide, or other material with high thermal conductivity.

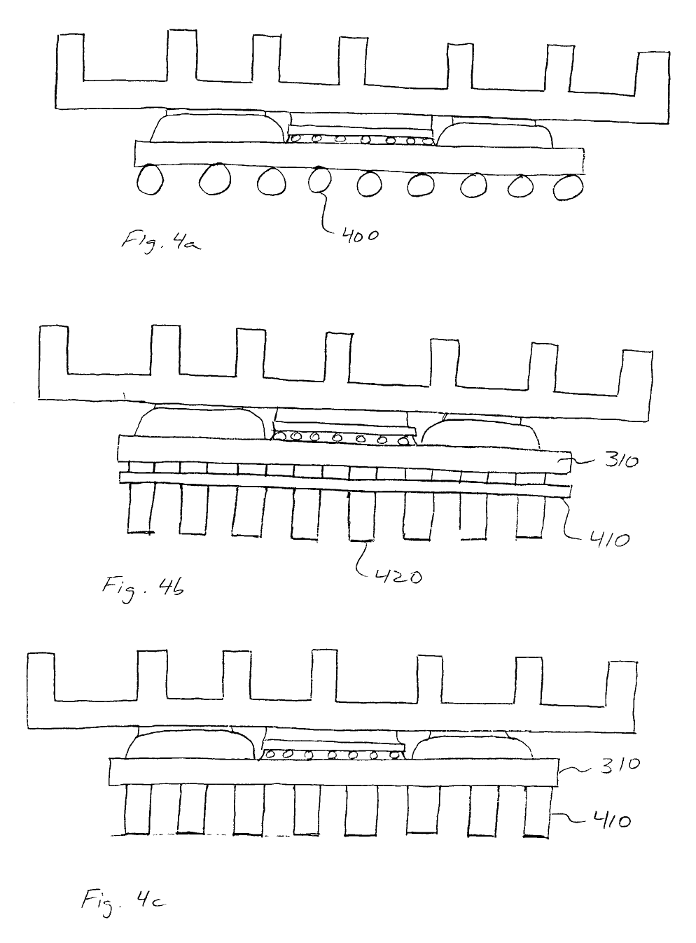

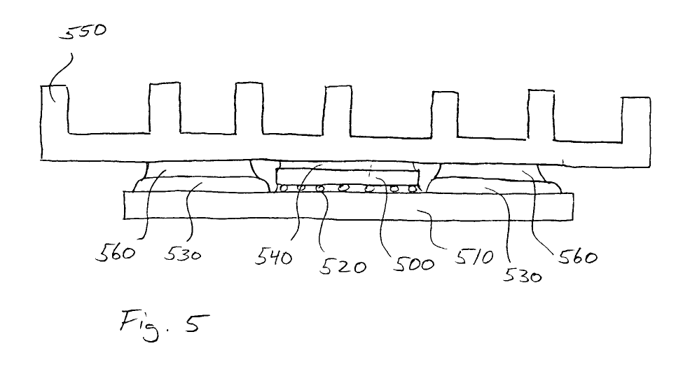

FIGS. 4a to 4c show three different means for coupling the package assembly to a next higher level of interconnection (a printed circuit board, for example). In FIG. 4a, solder balls 400 are preferably tin/lead or a lead-free alternative such as tin/silver. They are approximately 300 μm in diameter in this embodiment. In FIG. 4b, the interconnection is achieved using a ceramic interposer 410, which supports columns 420. The tops of columns 420 are attached to substrate 310 using solder, for example. Columns 420 may be made of high-melting point solder, a composite of high- and low-melting point solder, or a metal such as copper. Interposer 410 is made of ceramic in this embodiment, but may of course be made of other suitable insulative materials. In FIG. 4c, the columns are mounted directly to the bottom of substrate 310 using solder, for example, or other suitable material.

FIG. 5 is an example of a spacer thickness that results in a positive offset with respect to the chip backside. As in the embodiment above, chip 500 is mounted to substrate 510 with solder bumps 520. Spacer 530 surrounds chip 500, but in this case the top surface of spacer 530 is lower than the stack height of the bumps plus the chip. Thus, the weight of heatsink 550 is primarily resting on chip 500. Note that in this embodiment, thermal conductor 540 can be made thinner than the adhesive 560 used to attach heatsink 550 to spacer 530. Therefore, depending upon the modulus of elasticity of the adhesive that is used, a fairly compressive and flexible spacer stack can be achieved even if a high modulus material is used for the spacer 530 itself.

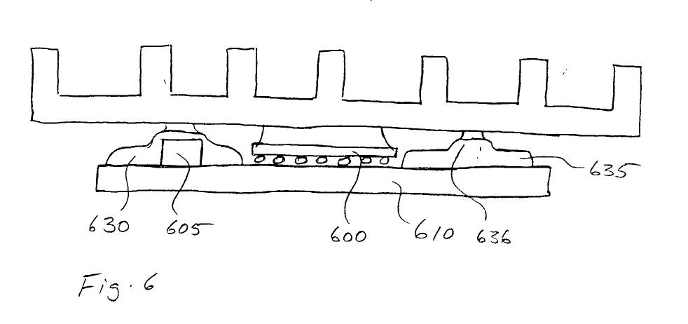

In FIG. 6, a passive component 605, such as a chip capacitor, for example, is mounted on the substrate 610 along with chip 600. The spacer 630 is molded over the capacitor 605. Here, the height of the capacitor extends above the surrounding spacer, though the cap is coated with mold compound. The top surface of the capacitor 605, plus the covering mold compound, sets the total standoff height. As in the embodiments described above, the standoff can be selected to produce a positive or negative offset with respect to the chip backside. Note also that the spacer can be designed to incorporate such a standoff feature in the absence of an underlying component as well (as for the portion 635 of the spacer that is shown on the opposite side of chip 610 from the side on which capacitor 605 is mounted). A molded standoff feature 636 such as is shown extending above spacer portion 635 can offer the package designer a certain degree of mechanical flexibility and compressibility of the heatsink/spacer interface even when using a very high modulus spacer material.

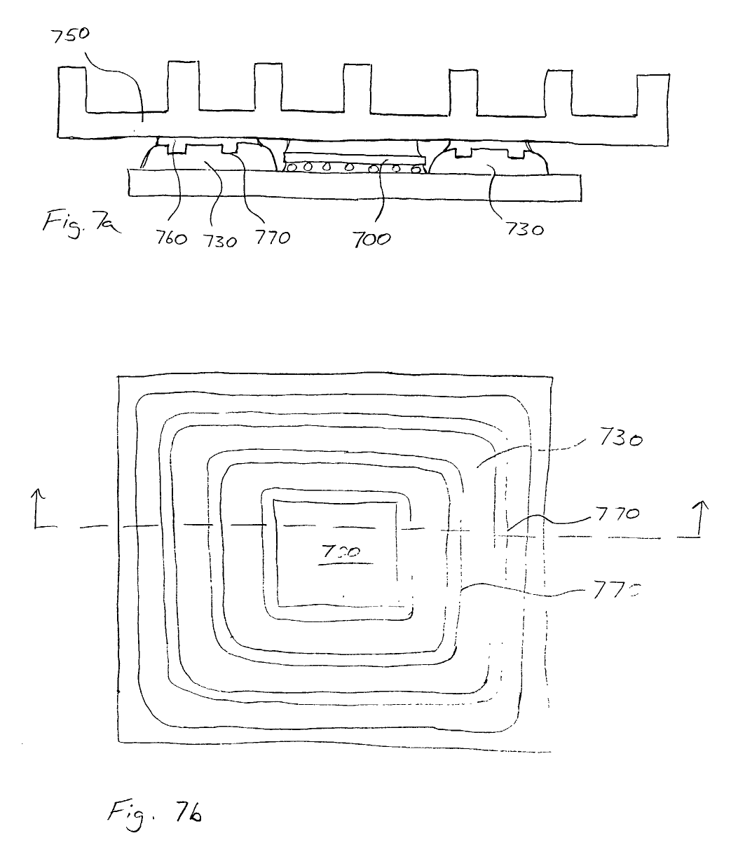

Another embodiment of the invention, shown in FIGS. 7a and 7b, includes texture features 770 in the surface of the spacer ring 730 that surrounds chip 700. (Note that for the sake of clarity FIG. 7b shows the structure of FIG. 7a without the heatsink 750 and thermal compound or adhesive.) The texture feature 770 enhances the adhesion of heatsink 750 to spacer 730 by providing additional surface area over which adhesive 760 establishes the bond between heatsink 750 and spacer 730. The texture features shown in FIGS. 7a and 7b consist of concentric grooves, but it should be appreciated that other forms of texture or roughness in the surface of spacer ring 730 could achieve the intended advantage. In this embodiment, grooves 770 are approximately 250 μm deep and 250 μm wide, a sufficient size to promote the flow of adhesive 760 into the grooves. The texture feature can be formed by including relief features in the mold used to form the spacer ring, for example. While the grooves in this embodiment are relatively large, one skilled in the art will appreciate that smaller features are possible as well. The minimum size of the texture feature is limited in the case of film-assisted molding (described below), by the thickness of the film used to coat the mold cavity. In this case the film is assumed to be approximately 25 μm in thickness, which easily allows the formation of the 250 μm square groove. A thinner film could be used to produce features smaller in dimension.

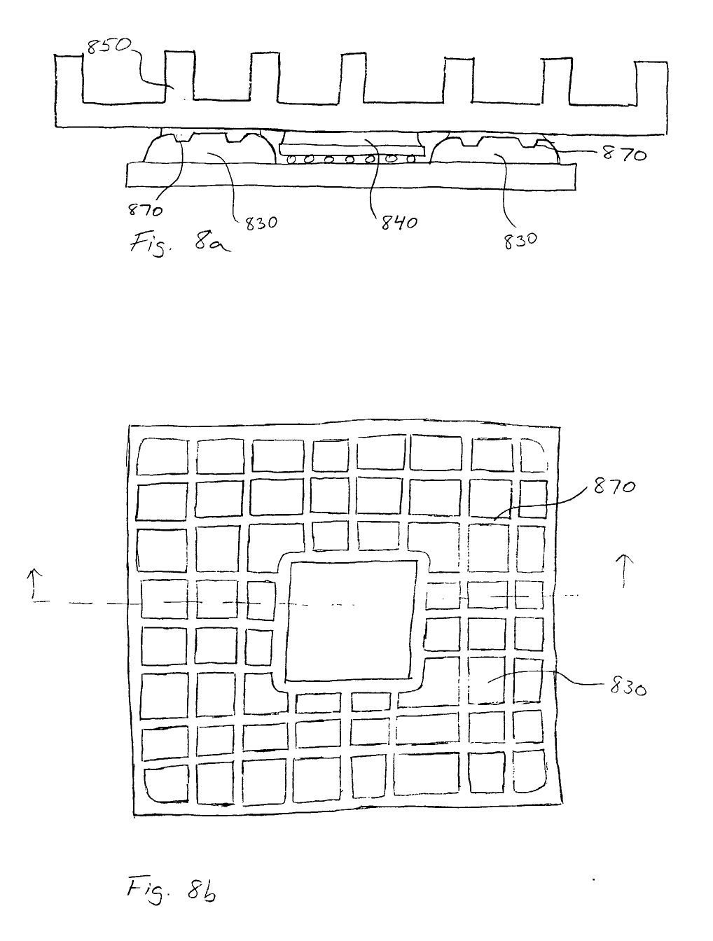

FIGS. 8a and 8b show another form of texturing of the surface of the spacer. (Note again that for the sake of clarity FIG. 8b shows the structure of FIG. 8a without the heatsink 850 and thermal compound or adhesive). In this embodiment, spacer 830 is patterned in a grid of grooves 870, some of which end adjacent to the location of chip 800. The grooves in this arrangement therefore are capable of acting as an escape path from the region surrounding the chip for any excess thermal compound 840 that may be applied between the chip and the heatsink. This embodiment also illustrates an example of the shaping of the grooves that is possible. The sloped sides of grooves 870, shown in cross-section in FIG. 8a, can help to ensure the flow of adhesive into the grooves.

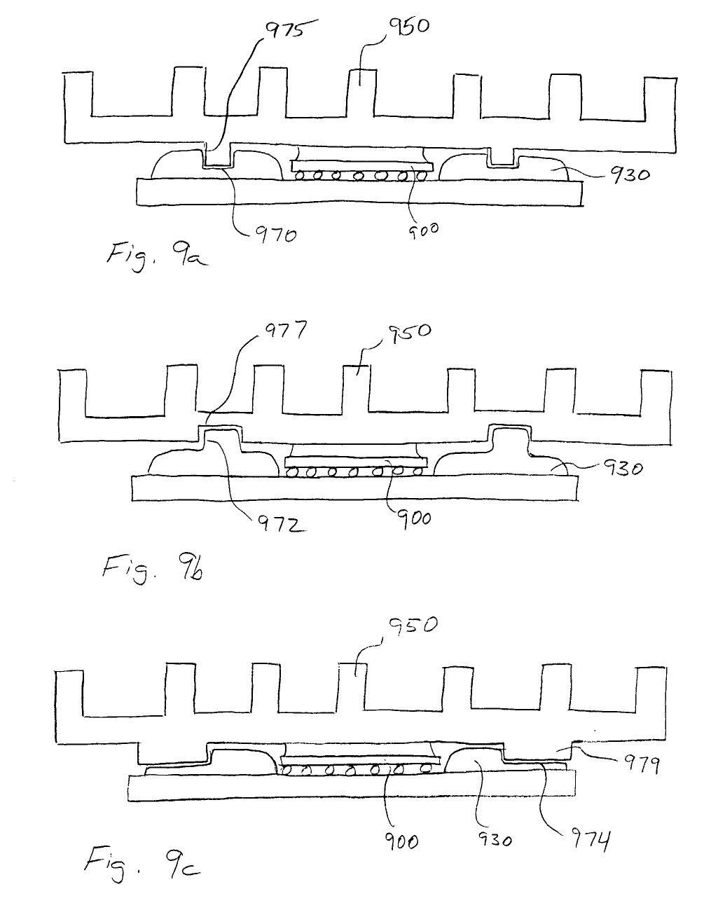

FIGS. 9a, 9b, and 9c show embodiments in which spacer 930 is adapted with key-like features to facilitate positioning and aligning heatsink 950 over the substrate. This approach is also useful when a temporary (i.e. removable) cap (not shown) is to be placed over the chip 900 for protection during processing, for example. In FIG. 9a, the spacer is molded to produce a depression 970 or intrusion into the surface of the spacer 930. The depression matches a key 975 formed on the underside of heatsink 950. The embodiment shown in FIG. 9b is the complement of the structure shown in FIG. 9a. In FIG. 9b, the spacer 930 is molded to produce a protrusion 972 on its surface designed to fit into a corresponding depression 977 in the bottom surface of the heatsink 950. In FIG. 9c, the spacer 930 includes a cut-out 974 into which a relatively wide lip 979 on the bottom side of the heatsink fits. It may be appreciated that configurations other than those shown could assist in positioning and holding a heatsink or cap in place over the substrate.

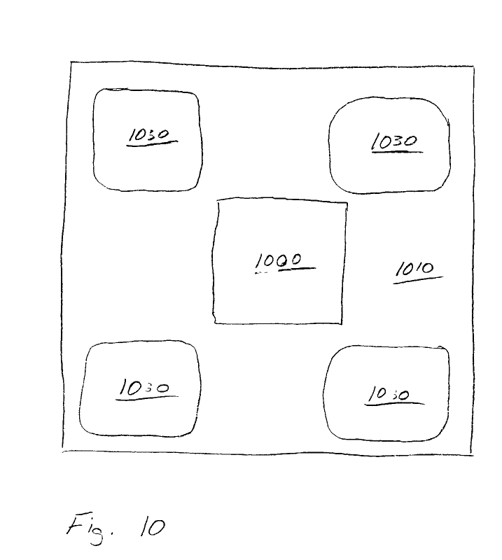

In the embodiment shown in FIG. 10, the spacer ring of the embodiments described above is replaced with spacer patches 1030 arranged on substrate 1010 around chip 1000. The use of isolated patches allows for less total spacer material on the substrate 1010, while still providing the standoff function mentioned above as an advantage of the spacer ring. This approach could be advantageous for substrate materials prone to flex during thermal cycling. The amount and temperature expansion characteristics of the spacer material can thus be tailored to the temperature-induced flex characteristics of the substrate. This approach also allows for ready access to the substrate surface after the spacers have been formed, an advantage in situations requiring rework, for example. The features of the foregoing embodiments are applicable to this embodiment as well. The negative offset (FIG. 3), the positive offset (FIG. 5), the molded standoffs (FIG. 6), the texture features (FIGS. 7 and 8), and the key-like features (FIG. 9) may be used to advantage for these discontinuous patches as well as for the continuous spacer rings described above.

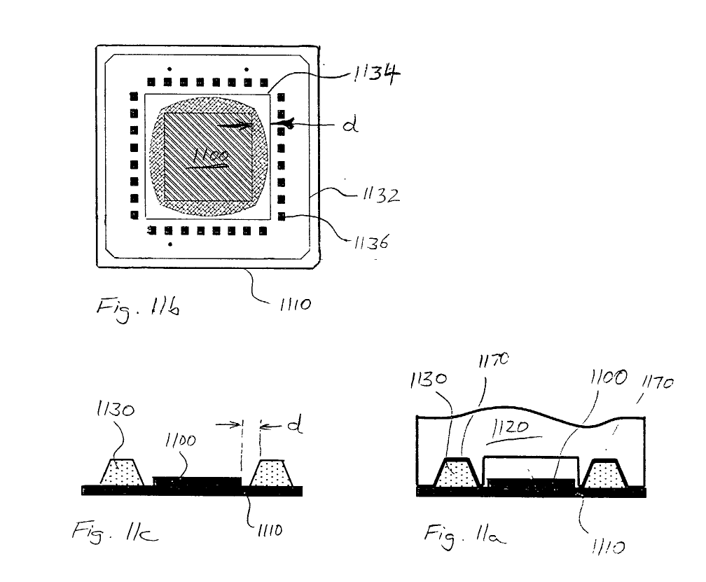

The molded spacers used in the above embodiments can be formed using conventional or film-assisted transfer molding techniques, for example. In FIG. 11a mold die 1120 is placed over substrate 1110 and chip 1100. Mold compound 1130 is flowed into cavities 1170 using standard molding techniques. FIG. 11b is a plan view of the structure shown in FIG. 11a showing the outside 1132 and inside 1134 boundaries of the molded spacer. Passive components 1136 are covered by mold compound 1130. Note that in this embodiment, the inside boundary 1134 of the mold compound is a distance d from the edge of chip 1100. FIG. 11c is a cross-sectional view of the structure shown in FIG. 11b. It should be appreciated that in an alternative approach, the mold die 1120 could be lined with a film that facilitates removal of the substrate from the mold die after molding. The film can also assist in sealing cavities 1170 to keep mold compound from inadvertently moving outside the cavities during the molding process.

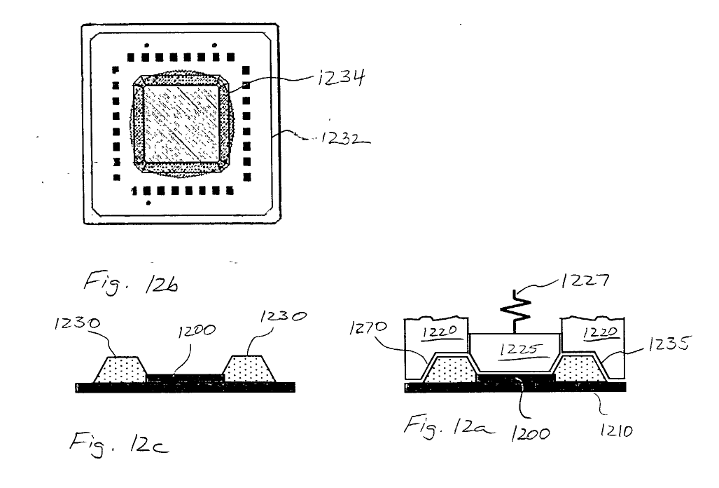

Another molding method is illustrated in FIGS. 12a, b, and c. In FIG. 12a, mold die 1220 includes an opening over chip 1200. The mold cavity 1270 is formed by mold die 1220 as well as plunger 1225, which is pressed onto chip 1200 through the opening in mold die 1220 using a spring 1227 or similar method of applying force. Film 1235 lines the cavities 1270 that surround chip 1200. The film helps seal the cavities 1270 and prevents mold flash on chip 1200 that can result from mold compound leaking out of the cavity and into the interface between plunger 1225 and chip 1200. Once plunger 1225 is in place, mold compound is flowed into cavities 1270 as in conventional molding techniques. FIG. 12b is a plan view showing the outside 1232 and inside 1234 boundaries of the molded spacer. Note that the inside boundary 1234 is chamfered as shown in FIG. 12a and that it abuts chip 1200. This results in a molded spacer 1230 in FIG. 12c that abuts the edge of chip 1200. The molded spacer abutting chip 1200 can help protect chip 1200 and can assist in containing thermal compound (not shown) that may be applied between the chip and a heatsink (not shown) placed over the chip.

In either the molding approach shown in FIG. 11 or that shown in FIG. 12, the texture and key-like features shown in FIGS. 7-9 can be produced by forming the mold die to include appropriate relief features. If a film assisted molding technique is used, allowance should be made in designing the texture and key-like features for the film that lines the mold cavities. A variety of film thicknesses are available, but 25 μm is commonly used when it is necessary to define features in a molded surface.

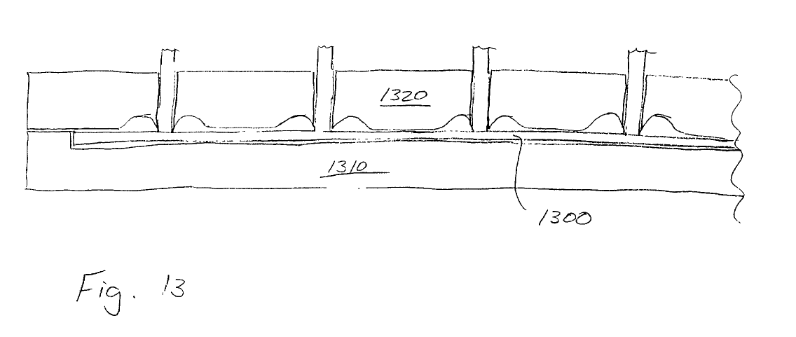

FIGS. 11 and 12 illustrate a single-substrate mold. A block mold can be employed in the alternative. In FIG. 13, a sheet of substrate material 1210 is placed in a block mold cavity formed of lower plate 1210 and mold die 1220 with features as described in FIGS. 11 and 12, for example. In FIG. 13, the plunger technique shown in FIG. 12 is used. The process is similar to that described above, except that it is applied to many substrates simultaneously. Following molding, the assembly is singulated (e.g. by sawing) to produce individual substrates, each having the desired molded spacer.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as claimed hereinbelow.

We claim:

1. A packaged integrated circuit, comprising:
a substrate having first and second opposing surfaces, wherein said first surface comprises a central chip pad location and a peripheral area surrounding said chip pad location, at least a portion of said peripheral area covered by a spacer;
an integrated circuit chip mounted on said chip pad location;
a heatsink mounted over said first surface of said substrate and attached to said chip and said spacer.

2. The packaged integrated circuit of claim 1, wherein said spacer is continuous and surrounds said chip pad location.

3. The packaged integrated circuit of claim 1, wherein said spacer is discontinuous and exists at discrete locations in said peripheral area.

4. The packaged integrated circuit of claim 1, wherein a topmost surface of said integrated circuit is lower than a top surface of said spacer.

5. The packaged integrated circuit of claim 1, wherein a topmost surface of said integrated circuit is higher than a top surface of said spacer.

6. The packaged integrated circuit of claim 1, wherein a topmost surface of said spacer includes texture features.

7. The packaged integrated circuit of claim 6, wherein said texture features comprise a plurality of grooves, as least some which having openings adjacent said chip pad location.

8. The packaged integrated circuit of claim 1, wherein said spacer covers passive components mounted on said first surface of said substrate.

9. The packaged integrated circuit of claim 1, wherein said spacer is molded epoxy.

10. The packaged integrated circuit of claim 1, wherein said spacer and said heatsink include corresponding key-like features.

11. A packaged integrated circuit, comprising:
a substrate having first and second opposing surfaces, wherein said first surface comprises a central chip pad location and a peripheral area surrounding said chip pad location, said peripheral area covered with mold compound, said mold compound having a certain thickness;
an integrated circuit chip mounted on said chip pad location, said chip having a top surface away from said first surface of said substrate, said top surface of said chip being a distance from said first surface of said substrate that is less than said certain thickness of said mold compound;
a heatsink mounted over said first surface of said substrate and attached to said chip and said mold compound.

12. The packaged integrated circuit of claim 11, wherein said mold compound is continuous and surrounds said chip pad location.

13. The packaged integrated circuit of claim 11, wherein said mold compound is discontinuous and exists at discrete locations in said peripheral area.

14. The packaged integrated circuit of claim 11, further comprising a passive component mounted on said first surface of said substrate, wherein said mold compound covers said passive component.

15. The packaged integrated circuit of claim 11, wherein a surface of said mold compound adjacent said heatsink includes texture features.

16. The packaged integrated circuit of claim 15, wherein said texture features comprise a plurality of grooves, as least some which having openings adjacent said chip pad location.

17. The packaged integrated circuit of claim 11, wherein said spacer and said heatsink include corresponding key-like features.

18. A method of packaging an integrated circuit, comprising the steps of:
providing a substrate having first and second opposing surfaces, wherein said first surface comprises a central chip pad location and a peripheral area surrounding said chip pad location;
covering at least a portion of said peripheral area with a spacer;
mounting an integrated circuit chip on said chip pad location; and
attaching a heatsink to said chip and to said spacer.

19. The method of claim 18, wherein said step of covering said portion of said peripheral area with a spacer comprises molding a ring on said first surface of said substrate, said ring surrounding said central chip pad location.

20. The method of claim 18, wherein said step of covering said portion of said peripheral area with a spacer comprises molding discontinuous patches on said substrate around said central chip pad location.

21. The method of claim 19, wherein said step of molding comprises molding texture features in said ring.

22. The method of claim 20, wherein said step of molding comprises molding texture features in said patches.

23. The method of claim 15, further comprising the step of mounting a passive component on said first surface of said substrate prior to said step of covering at least a portion of said peripheral area with said spacer, and further wherein said spacer covers said passive component.
